(19) United States
(12) Patent Application Publication
(10) Pub. No.: US 2004/0166662 A1
(43) Pub. Date: Aug. 26, 2004

(54) MEMS wafer level chip scale package

(75) Inventor: Kuo-Lung Lei, San Jose, CA (US)

Correspondence Address: TUNG & ASSOCIATES, Suite 120, 838 W. Long Lake Road, Bloomfield Hills, MI, 48302, US

(73) Assignee: Aptos Corporation

(21) Appl. No.: 10/371,042

(22) Filed: Feb. 21, 2003

(51) Int. Cl. H01L 21/44

(52) U.S. Cl. 438/614

(57) ABSTRACT

A method of forming a wafer level chip scale package including forming a trench through the semiconductor wafer at a location between two adjacent to chip portions and forming a backside under bump metallurgy connection to an under bump metallurgy on the front face of the semiconductor wafer for each chip portion.

### FIELD OF THE INVENTION

This invention relates to wafer level chip scale packages, individual dies formed therefrom and methods of making the same. One embodiment relates to a wafer level chip scale package for MEMS type semiconductor devices, individual dies and methods of making the same.

### BACKGROUND OF THE INVENTION

Many electronic devices are very sensitive and need to be protected from harsh external parameters, including various potentially damaging contaminants that may be present in the environments that such devices are employed. The use a hermetic seals has proven to be a very effective method for providing protection for such devices. Known hermetically sealed packages have been made from metal, class, or ceramic, any means of sealing, such as soldering or welding. Making such a hermetic seal packaging structures is an expensive process for manufacturing and quality control.

Traditionally, individual electronic devices to be sealed are constructed from a wafer and individualized. The electronic devices are then mounted inside of a package which is suitable for hermetic scaling. Next, conductive wires or ribbon bonding is performed between electric terminals located inside of the package and the terminals of the electronic device itself. This kind of interconnection enables the electronic device to communicate with outside systems. Then, the package is sealed by metal welding or seam sealing. Finally, each individual package in part are electrically tested to determine electrical specifications. Traditionally, the process for hermetical seal packaging and electrical testing have been carried out on each individual device. Traditional packaging techniques utilize one time wafer level testing, and one time device level testing. Such traditional packaging techniques are subject to contamination during dicing the wafer into fragile dies. These fragile dies require special handling tools to perform subsequent operations thereon. However, types of semiconductor devices that contain moving structures, like accelerometers, micro-mirrors, pressure sensors and the like, need wafer level protection before wafer dicing and die handling. Advances in making wafer level chip scale packages, particularly wafer level chip scale packages for MEMs type semiconductor devices is needed as will be evidenced from the following survey of a number of specific prior art references.

A number of wafer level semiconductor packages and methods of making semiconductor devices are known to those skilled in the art. Kong et al. U.S. Pat. No. 5,448,014 discloses a method of sealing and electrical testing of electronic devices, particularly for surface acoustic wave devices. A mass simultaneous sealing and electrical connection at the wafer level is accomplished using substrates with hermetically sealed and electrically conductive via holes.

Warfield, U.S. Pat. No. 5,604,160 discloses a cap wafer used to package semiconductor devices on a device wafer. Successful etching processes form a plurality of partially etched cavities extending from a front surface of the cap wafer ino the cap wafer. The pattern of the plurality etched cavities is determined in accordance with the pattern of dies on the semiconductor device wafer. The cap wafer is aligned with the device wafer and bonded to the device wafer using a glass frit as a bonding agent. After being bonded to the device wafer, the cap wafer is thinned from the backside until the back surface of the cap wafer reaches the plurality of the etched cavities. The device wafer is then diced into distinct dies.

Ohsawa et al., U.S. Pat. No. 5,786,239 discloses a method of manufacturing a semiconductor package wherein a plurality of leads and a large number of minute convex portions are respectively formed by plating a surface of a metal base and an outer peripheral area of the leads thereon. An insulating film for holding each of the leads is formed. A solder resist film for holding each of the leads is formed. A solder resist film is formed selectively on a portion including the outer peripheral area having the minute convex portions thereon. A projecting electrode is formed on the outer lead portion of each of the leads through an opening of the solder resist film on an outer lead portion of each of leads. A metal base is selectively removed except a joint portion thereof on an outer periphery to separate the respective leads. Inner lead portions of the leads and a semiconductor chip are jointed together. The joint portion of the metal base is cut off.

Badechi, U.S. Pat. No. 6,022,758 discloses a process of forming a package integrated circuit by aperturing a discrete packaging layer attached on a silicon substrate. A plurality of solder leads are formed on the layer. Electrical connections are formed from the leads to pads on the substrate.

Martin et al., U.S. Pat. No. 6,323,550 B1 discloses a die having a part that is sealed with a cap. The seal can be hermetic or non-hermetic. If hermetic, a layer of glass or metal is formed in the surface of the die, and the cap has a layer of glass or metal at the peripheral area so that, when heated, the layers formed a hermetic seal. A non-hermetic seal can be formed by bonding a cap with a patterned adhesive. The cap, which can be silicon or can be a metal paddle, is electrically coupled to a fixed voltage to shield the part of the die.

### SUMMARY OF THE INVENTION

One embodiment of the invention includes a process comprising:

providing a semiconductor wafer having an a plurality of the chip portions formed therein, said semiconductor wafer having a first face and an opposite second face, and a first under bump metallurgy formed on a portion of the first face of the semiconductor wafer for each of the chip portions;

forming a trench in the semiconductor wafer from the second face to a location near the first under bump metallurgy formed on the first face of the semiconductor wafer and wherein the trench is formed so as to remove portions of the semiconductor wafer from two adjacent chip portions, the trench being defined by walls of each of the two adjacent chip portions.

Another embodiment comprises a process of making a semiconductor package comprising:

providing a semiconductor wafer having a plurality of adjacent chip portions defined therein, each chip portion including an active area and a bond pad formed on a first face of the semiconductor wafer and a passivation layer on a first face of the semiconductor wafer formed over a portion of the semiconductor wafer and a portion of the bond pad, a first under bump metallurgy portion overlying a portion of the passivation layer, a second under bump metallurgy portion overlying the bond pad, and a third under bump metallurgy portion overlying the passivation layer;

providing a cap wafer having a plurality of cap portions each corresponding to a chip portion of the semiconductor wafer, the cap wafer having an under bump metallurgy formed over at least a portion of a first face thereof and across adjacent cap portions, a dielectric layer selectively deposited over the under bump metallurgy for each cap portion, and a patterning layer selectively deposited over each cap portion and over the dielectric layer of each cap portion, the patterning layer having at least first, second and third openings defined therein down to the under bump metallurgy of each cap portion; and wherein the second and third openings are separated by the dielectric layer;

depositing an electrically conductive material over the cap wafer and into the first, second and third openings in the patterning layer and removing the patterning layer to provide a sealing ring portion formed by the material deposited in the first opening in the patterning layer, and second and third pre-bump portions formed by the electrically conductive material deposited in the second and third openings in the patterning layer respectively;

reflowing the electrically conductive material to form bump structures;

bonding the cap wafer to the semiconductor wafer wherein the sealing ring portion bonds to the first under bump metallurgy portion of the semiconductor wafer, and the bump structures formed by the material deposited in the second and third openings of the patterning layer on the cap wafer are bonded to the second under bump metallurgy portion and the third under bump metallurgy portion of the semiconductor wafer respectively;

forming a trench in the semiconductor wafer from a second face through to the passivation layer on the first face of the semiconductor wafer and depositing a dielectric layer over the second face of the semiconductor wafer and down into the trench and over the passivation layer of the first face of the semiconductor wafer;

forming a via in the dielectric layer and the passivation layer down to the third under bump metallurgy portion of the first face of the semiconductor wafer;

depositing an under bump metallurgy over the second face of the semiconductor wafer and down into the trench and into the via to contact the third portion of the under bump metallurgy of the first face of the semiconductor wafer;

forming a photoresist layer over the second face of the semiconductor wafer and providing openings therein overlying a portion of the under bump metallurgy overlying the second face of the semiconductor wafer;

depositing an electrically conductive material into the opening in the photoresist layer over the second face of the semiconductor wafer and removing the photoresist layer,

selectively removing excess under bump metallurgy on a second face of the semiconductor wafer to form a fourth pre-bump structure leaving under bump metallurgy extending from the fourth pre-bump structure on the second face of the semiconductor wafer to the third portion of the under bump metallurgy on the first face of the semiconductor wafer;

reflowing the fourth pre-bump to form a fourth bump on the under bump metallurgy overlying the second face of the semiconductor wafer;

testing each chip portion of the semiconductor wafer for individual electrical probing data associative with each die to be made therefrom;

cutting the semiconductor wafer and the cap wafer adjacent the third under bump metallurgy portion formed on the first face of the semiconductor wafer so that an electrical connection is provided between the fourth bump on the under bump metallurgy overlying the second face of the semiconductor wafer down into the trench and connecting to the third portion of the under bump metallurgy on the first face of the semiconductor wafer and to the bond pad on the first face of the semiconductor wafer through the electrically conductive material deposited in the second and third openings of the photoresist layer formed over the cap wafer.

In another embodiment the semiconductor wafer further includes a movable structure defined therein and wherein the sealing ring portion and the cap portion surrounds the movable structure provides a hermetic seal around the same.

Another embodiment comprises a process of making a semiconductor package comprising:

providing a semiconductor wafer having a first face and an opposite second face, and the first face of the semiconductor wafer comprising a bond pad, a passivation layer overlying a portion of the bond pad and a first under bump metallurgy overlying a portion of the passivation layer;

securing a cap wafer to the first face of the semiconductor wafer;

forming a trench in the semiconductor wafer extending from the second face to the passivation layer of the first face of the semiconductor wafer;

forming a via opening through the passivation layer to the first under bump metallurgy of the first face of the semiconductor wafer;

forming a second under bump metallurgy overlying at least a portion of the second face of the semiconductor wafer and into the trench and the via opening so that the second under bump metallurgy contacts a first under bump metallurgy;

forming an electrically conductive bump on a portion of the second under bump metallurgy overlying the second face of the semiconductor wafer; and

cutting the semiconductor wafer and the cap wafer so that the second under bump metallurgy and the first under bump metallurgy stay in electrical contact.

In another embodiment the semiconductor wafer further includes a bond pad and the first under bump metallurgy is electrically connected to the bond pad.

Another embodiment further including an under bump metallurgy on the cap wafer, and a bump structure on the first under bump metallurgy and a bump structure on the bond pad, and wherein the bump structure on the bond pad and the bump structure on the first under bump metallurgy are bonded to the under bump metallurgy on the cap wafer.

Another embodiment further including a movable structure defined in the semiconductor wafer and further including a sealing ring surrounding the movable structure and extending between the semiconductor wafer and the cap wafer.

Another embodiment comprises a process comprising:

providing a semiconductor wafer having an a plurality of the chip portions formed therein, said semiconductor wafer having a first face and an opposite second face, and a first under bump metallurgy formed on a portion of the first face of the semiconductor wafer for each of the chip portions;

forming a trench in the semiconductor wafer from the second face to a location near the first under bump metallurgy formed on the first face of the semiconductor wafer and wherein the trench is formed so as to remove portions of the semiconductor wafer from two adjacent chip portions, the trench being defined by walls of each of the two adjacent chip portions;

forming a second under bump metallurgy and over at least a portion of the second face of the semiconductor wafer and over the walls defining the trench and electrically connecting the first under bump metallurgy and second under bump metallurgy together.

These and other embodiments of the present invention will become apparent from the following brief description of the drawings, detailed description of the preferred embodiments, and appended claims and drawings.

### BRIEF DESCRIPTION OF THE DRAWINGS

FIG. 1 illustrates a first substrate such as a semiconductor device wafer including bond pads and under bump metallurgy for at least a first chip and a second chip portion for use in a method according to one embodiment of the present invention.

FIG. 2 illustrates a second substrate such as a cap wafer and with the under bump metallurgy, a dielectric layer, and photoresist patternization for use in a method according to one embodiment of the present invention.

FIG. 3 illustrates depositing an electrically conductive material such as plating a eutectic solder for providing a sealing means and solder bump on the cap wafer of FIG. 2 according to one embodiment of present invention.

FIG. 4 illustrates a method including an under bump metallurgy etch back and solder reflow of the cap wafer structure shown in FIG. 3 according to one embodiment of the present invention.

FIG. 5 illustrates the alignment of the first substrate and a second substrate and bonding of the substrates together using for example, thermal, radiation, or ultrasonic energy according to one embodiment of the present invention.

FIG. 6 illustrates a method of backside etching of the first substrate and depositing a dielectric layer over the backside of the first substrate to prepare for via streets according to one embodiment of the present invention.

FIG. 7 illustrates the etching of vias and under bump metallurgy deposition over the backside of the first substrate according to one embodiment of the present invention.

FIG. 8 illustrates a method of backside dielectric layer patternization and bump resist lithography to define a redistribution trace by dielectric pattern and construction of bump shape by photolithography according to one embodiment of the present invention.

FIG. 9 illustrates the depositing of electrically conductive material and removing the photoresist, such as electroplating a flip chip bonding material and etching back excess under bump metallurgy according to one embodiment of the present invention.

FIG. 10 illustrates a method of forming an electrically conductive bump such as a solder ball by bump reflow and thereafter dicing the wafer into individual dies according to one embodiment of the present invention.

FIG. 11 illustrates an individual semiconductor die package according to one embodiment of the present invention.

### DETAILED DESCRIPTION OF THE PREFERRED EMBODIMENTS

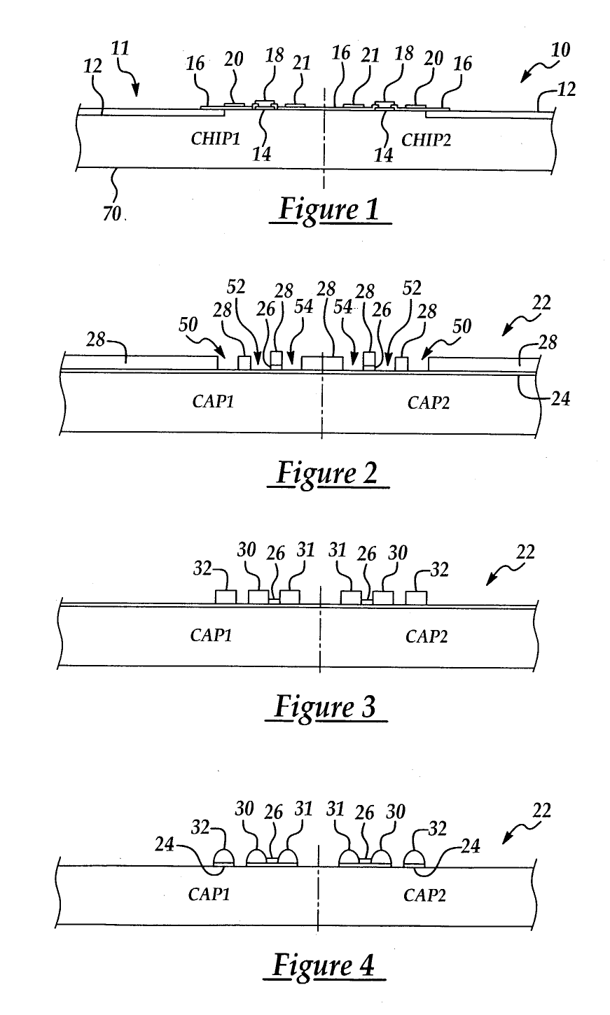

According to the present invention a first substrate such as a semiconductor wafer 10 is provided as illustrated in FIG. 1. The semiconductor wafer 10 includes active regions 12 that need protection. The active regions 12 or other portions of the semiconductor wafer for each chip portion may include the movable structures such as accelerometers, gyroscopes, micro-mirrors 12 and the like. Bond pads 14 are provided on a first face 11 of the semiconductor wafer and selective portions of the semiconductor wafer are covered by a passivation layer 16 having an openings therein exposing a portion of bond pad, and an electrically conductive structure such as an under bump metallurgy or an electrical redistribution trace 18 may be deposited in over the bond pad 14 as desired. A common under bump metallurgy 18 used for 37/63 tin/lead solder is titanium/copper in 1000 angstroms/4000 angstroms thicknesses respectively. Additional under bump structures 20, 21 may also be provided on the semiconductor wafer for connection to a bump structure on a protective cap as will be described hereafter. As such the under bump metallurgy includes first, second and third portions 18, 20 and 21 respectively. A semiconductor wafer as illustrated in FIG. 1 includes a first chip portion and a second chip portion. The dashed line in the FIG. 1-10 illustrates the location where the semiconductor wafer will be cut to produce individual first and second chip portions. The electrically conductive structure 18 (e.g., under bump metallurgy or electrical restribution trace) extends generally horizontally from the bond pad 14.

FIG. 2 illustrates a second substrate such as a cap wafer 22. The cap wafer 22 may be made from any suitable material known to those skilled in the art including for example, but not limited to, silicon based materials, glass based materials or ceramic based materials. The cap wafer 22 may provide both protecting and functional purposes such as forming a microlens, alignment structures or just flat surface on the bottom side. An under bump metallurgy 24 is provided over at least a portion of the cap wafer 22. A dielectric layer 26 is selectively deposited at various locations to isolate electrically conductive structures to be formed hereafter. The dielectric layer 26 may be any of a variety of materials known to those skilled in the art including, but not limited to, a polymer, silicon nitride, silicon oxy-nitride or silicon dioxide. The dielectric layer 26 provides device signal rerouting from one bond pad to another as will be apparent from the description of the sealed device provided hereafter. A patterned layer 28 such as a photoresist layer having first, second and third openings 50, 52 and 54 formed therein is formed over the under bump metallurgy 24 and the selectively deposited dielectric layer 26.

FIG. 3 illustrates the selective forming of the electrically conductive material in the openings 50, 52, 54 in the photoresist layer, such as depositing a solder material as described above, and stripping of the photoresist layer. The process provides pre-bump structures 30, 31 and a pre-sealing ring portion 32 on the surface of the cap wafer 22. The pre-sealing ring portion 32 is located at a position corresponding to edge of the active regions.

The pre-bump structures 30, 31 and pre-sealing ring portion 32 are used as mask and the excess under bump metallurgy that is exposed and not covered by these structures is etched back. The etching process may be dry or wet, the only requirement being that the etch is highly selective for the under bump metallurgy to the mask. This is followed by a reflow process that causes the pre-bump structures 30, 31 and the sealing ring portion 32 to flow into a ball like structures from their previous rectangular shaped. The reflow process can be accomplished using a conventional oven, infrared oven, or vacuum oven.

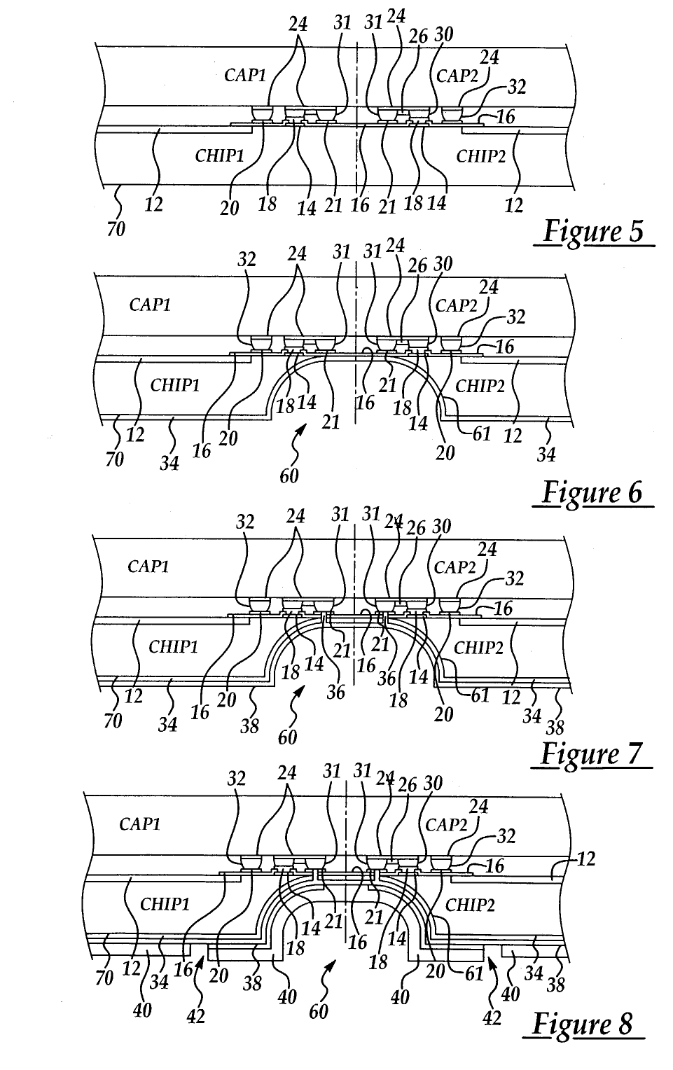

FIG. 5 illustrates the semiconductor wafer 10 and the cap wafer 22 being bonded together. In this process, there is a need to align the patterns of the structures 30, 31 and 32 and the cap wafer 22 with the bond pads and under bump structures 18, 20, 21 on the semiconductor wafer 10. The bonding may be accomplished by thermal, radiation or ultrasonic energy causing such structures 30, 31, 32 to reflow and attached to the associates under bump metallurgy on the semiconductor wafer 10. This process protects the active areas 12 wherein the reflown sealing ring structure 32 hermetically seals active areas 12 of the semiconductor device 10.

FIG. 6 illustrates the process of using the cap wafer 22 as a support for the semiconductor wafer 10 and forming a trench 60 in the semiconductor wafer 10, for example by etching using dry or wet process techniques. The trench 60 opening extends down to the passivation layer 16 on the semiconductor wafer 10. The trench 60 is defined by walls 61 left in each of the two adjacent chip portions. Thereafter, a dielectric layer and the 34 is deposited over the backside (second face 70) of the semiconductor wafer 10 and fills a portion of the trench and along the walls 61 and onto a portion of the passivation layer 16.

FIG. 7 illustrates the process of forming via openings 36 in the dielectric layer 34 down to one of the under bump metallurgy portion 21 corresponding to the outer electrically conductive bump portion 31. The via opening 36 extends all the way to the under bump metallurgy 21 underneath the bump structure 31. Another under bump metallurgy 38 is deposited over the backside of the semiconductor wafer 10 and the dielectric layer 34 and down into the via openings 36. The under bump metallurgy 38 may be deposited by any of a variety of methods including a plasma vapor deposition. Other possible methods of depositing the under bump metallurgy 38 include, but not limited to, electroplating or chemical vapor deposition.

FIG. 8 illustrates the process of forming any patterning layer 40 with openings 42 selectively positioned therein. The patterning layer 40 may be a photoresist layer which is deposited, developed and patterned in a manner known to those skilled in the art. The openings 42 overlying a portion of the under bump metallurgy 38.

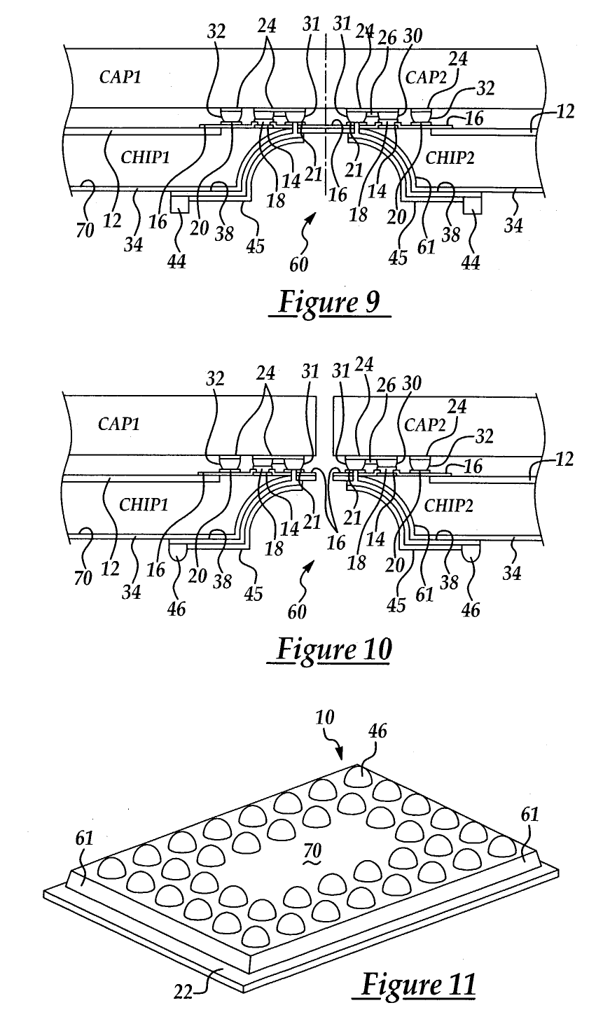

As shown in FIG. 9, an electrically conductive material 44 is deposited into the opening 42 in the patterning layer 40 and the patterning layer 40 stripped. The electrically conductive material 44 may be any material known to those skilled in the art, including, but not limited to, gold, silver, Ni or solder, or alloy thereof. There's no need for the electrically conductive material 44 to have a lower melting point then as the other electrically conductive material used for structures 30, 31, 32 as previously described. The photoresist layer 40 and may then be removed to by stripping. A dielectric trace 45 may be selectively deposited over a portion of the under bump metallurgy 38 that extends from the fourth pre-bump structure 44 to the third portion 21 the under bump metallurgy on the first face of the semiconductor wafer 10. The fourth pre-bump structure 44 and the dielectric trace 45 may be used as mask to selectively etch back excess under bump metallurgy as shown in FIG. 9.

As shown in FIG. 10, the fourth pre-bump structure 44 is reflow to form a fourth electrically conductive bump 46. After the reflowing as shown in FIG. 10, each chip portion (die) can be tested to obtain electric probing data. All of the data is final and isolate from the environment and there's no contamination after the wafer level chip scale packaging. Every die will be ready for use in a system after wafer dicing and will have final test data. Individual dies are formed by cutting the semiconductor wafer 10 and cap wafer 22. The resulting individual die each provided for electrical connection extending from the fourth bump structure 46 along the under bump metallurgy 38 to the bump structures 31 and 30. FIG. 11 illustrates an individual die including a semiconductor portion 10 with bump structure 46 and protective cap portion 22.

1. A process comprising:
providing a semiconductor wafer having an a plurality of the chip portions formed therein, said semiconductor wafer having a first face and an opposite second face, and a first under bump metallurgy formed on a portion of the first face of the semiconductor wafer for each of the chip portions;
forming a trench in the semiconductor wafer from the second face to a location near the first under bump metallurgy formed on the first face of the semiconductor wafer and wherein the trench is formed so as to remove portions of the semiconductor wafer from two adjacent chip portions, the trench being defined by walls of each of the two adjacent chip portions.

2. A process as set forth in claim 1 wherein the semiconductor wafer further comprises a passivation layer overlying at least a portion of the first face of the semiconductor wafer and underneath the first under bump metallurgy.

3. A process as set forth in claim 2 wherein the forming of the trench in the semiconductor wafer is conducted so that at least a portion of the passivation layer remains underlying the first under bump metallurgy.

4. A process as set forth in claim 1 further comprising depositing a second under bump metallurgy over the second face of the semiconductor and over the wall of each chip portion defining the trench.

5. A process as set forth in claim 4 further comprising cutting the first under bump metallurgy and the passivation layer and the second under bump metallurgy to singulate the first and second chip portions.

6. A process as set forth in claim 4 further comprising forming a via opening through the passivation layer to the first under bump metallurgy on the first face of the semiconductor wafer for each chip portion prior to depositing the second under bump metallurgy and so that the second under bump metallurgy extends into the via and the passivation layer and connects to the first under bump metallurgy.

7. A process as set forth in claim 6 further comprising, for each chip portion, forming an electrically conductive bump on a portion of the second under bump metallurgy overlying the second face of the semiconductor wafer.

8. A process as set forth in claim 7 further comprising cutting the semiconductor wafer so that the second under bump metallurgy and the first under bump metallurgy stay in electrical contact.

9. A process as set forth in claim 7 further comprising securing a cap wafer to the first face of the semiconductor wafer.

10. A process as set forth in claim 9 further comprising cutting the semiconductor wafer and the cap wafer to singulate each chip portion and so that the second under bump metallurgy and the first under bump metallurgy stay and electrical contact.

11. A process as set forth in claim 10 wherein the semiconductor wafer further comprises a bond pad and wherein the first under bump metallurgy is electrically connected to the bond pad.

12. A process as set forth in claim 11 further comprising an under bump metallurgy on the cap wafer, and a bump structure on the first under bump metallurgy and the bump structure on the bond pad, and wherein the bump structure on the bond pad and the bump structure and the first under bump metallurgy are bonded to the under bump metallurgy on the cap wafer.

13. A process as set forth in claim 12 further including a movable structure defined in the semiconductor wafer and further including a sealing ring surrounding the movable structure and extending between the semiconductor wafer and the cap wafer.

14. A process of making a semiconductor package comprising:
providing a semiconductor wafer having a first face and an opposite second face, and the first face of the semiconductor wafer comprising a bond pad, a passivation layer overlying a portion of the bond pad and a first under bump metallurgy overlying a portion of the passivation layer;
securing a cap wafer to the first face of the semiconductor wafer;
forming a trench in the semiconductor wafer extending from the second face to the passivation layer of the first face of the semiconductor wafer;
forming a via opening through the passivation layer to the first under bump metallurgy of the first face of the semiconductor wafer;
forming a second under bump metallurgy overlying at least a portion of the second face of the semiconductor wafer and into the trench and the via opening so that the second under bump metallurgy contacts a first under bump metallurgy;
forming an electrically conductive bump on a portion of the second under bump metallurgy overlying the second face of the semiconductor wafer; and
cutting the semiconductor wafer and the cap wafer so that the second under bump metallurgy and the first under bump metallurgy stay in electrical contact.

15. A process as set forth in claim 14 wherein the semiconductor wafer further includes a bond pad and the first under bump metallurgy is electrically connected to the bond pad.

16. A process as set forth in claim 15 further including an under bump metallurgy on the cap wafer, and a bump structure on the first under bump metallurgy and a bump structure on the bond pad, and wherein the bump structure on the bond pad and the bump structure on the first under bump metallurgy are bonded to the under bump metallurgy on the cap wafer.

17. A process as set forth in claim 16 further including a movable structure defined in the semiconductor wafer and further including a sealing ring surrounding the movable structure and extending between the semiconductor wafer and the cap wafer.

18. A process comprising:
providing a semiconductor wafer having an a plurality of the chip portions formed therein, said semiconductor wafer having a first face and an opposite second face, and a first under bump metallurgy formed on a portion of the first face of the semiconductor wafer for each of the chip portions;
forming a trench in the semiconductor wafer from the second face to a location near the first under bump metallurgy formed on the first face of the semiconductor wafer and wherein the trench is formed so as to remove portions of the semiconductor wafer from two adjacent chip portions, the trench being defined by walls of each of the two adjacent chip portions;
forming a second under bump metallurgy and over at least a portion of the second face of the semiconductor wafer and over the walls defining the trench and electrically connecting the first under bump metallurgy and second under bump metallurgy together.

19. A process of making a semiconductor package comprising:
providing a semiconductor wafer having a plurality of adjacent chip portions defined therein, each chip portion including an active area and a bond pad formed on a first face of the semiconductor wafer and a passivation layer on a first face of the semiconductor wafer formed over a portion of the semiconductor wafer and a portion of the bond pad, a first under bump metallurgy portion overlying a portion of the passivation layer, a second under bump metallurgy portion overlying the bond pad, and a third under bump metallurgy portion overlying the passivation layer;
providing a cap wafer having a plurality of cap portions each corresponding to a chip portion of the semiconductor wafer, the cap wafer having an under bump metallurgy formed over at least a portion of a first face thereof and across adjacent cap portions, a dielectric layer selectively deposited over the under bump metallurgy of each cap portion, and a patterning layer selectively deposited over each cap portion and over the dielectric layer of each cap portion, the patterning layer having at least first, second and third openings defined therein down to the under bump metallurgy of each cap portion; and wherein the second and third openings are separated by the dielectric layer;
depositing an electrically conductive material over the cap wafer and into the first, second and third openings in the patterning layer and removing the patterning layer to provide a sealing ring portion formed by the material deposited in the first opening in the patterning layer, and second and third pre-bump portions formed by the electrically conductive material deposited in the second and third openings in the patterning layer respectively;
reflowing the electrically conductive material to form bump structures;
bonding the cap wafer to the semiconductor wafer wherein the sealing ring portion bonds to the first under bump metallurgy portion of the semiconductor wafer, and the bump structures formed by the material deposited in the second and third openings of the patterning layer on the cap wafer are bonded to the second under bump metallurgy portion and the third under bump metallurgy portion of the semiconductor wafer respectively;
forming a trench in the semiconductor wafer from a second face through to the passivation layer on the first face of the semiconductor wafer and depositing a dielectric layer over the second face of the semiconductor wafer and down into the trench and over the passivation layer of the first face of the semiconductor wafer;
forming a via in the dielectric layer and the passivation layer down to the third under bump metallurgy portion of the first face of the semiconductor wafer;
depositing an under bump metallurgy over the second face of the semiconductor wafer and down into the trench and into the via to contact the third portion of the under bump metallurgy of the first face of the semiconductor wafer;
forming a photoresist layer over the second face of the semiconductor wafer and providing openings therein overlying a portion of the under bump metallurgy overlying the second face of the semiconductor wafer;
depositing an electrically conductive material into the opening in the photoresist layer over the second face of the semiconductor wafer and removing the photoresist layer,
selectively removing excess under bump metallurgy on a second face of the semiconductor wafer to form a fourth pre-bump structure leaving under bump metallurgy extending from the fourth pre-bump structure on the second face of the semiconductor wafer to the third portion of the under bump metallurgy on the first face of the semiconductor wafer;
reflowing the fourth pre-bump to form a fourth bump on the under bump metallurgy overlying the second face of the semiconductor wafer;
testing each chip portion of the semiconductor wafer for individual electrical probing data associative with each die to be made therefrom;
cutting the semiconductor wafer and the cap wafer adjacent the third under bump metallurgy portion formed on the first face of the semiconductor wafer so that an electrical connection is provided between the fourth bump on the under bump metallurgy overlying the second face of the semiconductor wafer down into the trench and connecting to the third portion of the under bump metallurgy on the first face of the semiconductor wafer and to the bond pad on the first face of the semiconductor wafer through the electrically conductive material deposited in the second and third openings of the photoresist layer formed over the cap wafer.

20. A process as set forth in claim 19 wherein the semiconductor wafer further includes a movable structure defined therein and wherein the sealing ring portion and the cap portion surrounds the movable structure provides a hermetic seal around the same.
